(19) United States
(12) Patent Application Publication
(10) Pub. No.: US 2008/0057601 A1
(43) Pub. Date: Mar. 6, 2008

(54) Method for manufacturing a white LED

(75) Inventor: In Hyuk Hwang, Seoul (KR)

Correspondence Address: LADAS & PARRY, 26 WEST 61ST STREET, NEW YORK, NY, 10023, US

(73) Assignee: MOKSAN ELECTRONIC CO., LTD.

(21) Appl. No.: 11/653,641

(22) Filed: Jan. 16, 2007

(30) Foreign Application Priority Data
Sep. 6, 2006 (KR) 10-2006-0085683

(51) Int. Cl. H01L 21/00

(52) U.S. Cl. 438/21

(57) ABSTRACT

A method for manufacturing a white LED is disclosed. The method for manufacturing a white LED comprises a die bonding step in which a blue chip is mounted on a lead frame; a wire bonding step in which the blue chip and lead frame both mounted on the lead frame in the die bonding step are electrically connected by a wire; a first lamp molding step in which a first lamp is formed on the blue chip which is electrically connected with the lead frame in the wire bonding step; a phosphorous material coating step in which a phosphorous material is coated on the first lamp formed in the first lamp molding step; and a second lamp molding step in which a second lamp is formed on the first lamp which is previously coated with the phosphorous material in the phosphorous material coating step.

### BACKGROUND OF THE INVENTION

1. Field of the Invention

The present invention relates to a method for manufacturing a white LED which emits a white light, and in particular to a method for manufacturing a white LED in which a luminance down phenomenon, which occurs by heat when a blue chip and a phosphorous material contact with each other, may be prevented by forming lamps through two lamp molding steps, and a long time storage is advantageously obtained from a first lamp molding step to a second lamp molding step, and a perfect white light may be emitted with less color deflection by uniformly coating a phosphorous material.

2. Description of the Background Art

The conventional white LED, which emits a white light, is manufactured through a process in which a blue chip is bonded on a lead frame using a conductive wire, and a resultant structure is coated by a phosphorous material and is molded by an epoxy resin.

However, when the white LED is manufactured by a conventional method, a luminance may be poor due to a heating by a direct contact between the blue chip and the phosphorous material, so that the quality may be deteriorated, and the life span may be shortened.

In addition, since it is needed to mold a lamp within a short time period so as to prevent a damage of a coated layer after a phosphorous material is coated on the blue chip, so that work efficiency becomes worse.

Since it is needed to coat a very small amount of phosphorous material on the blue chip, a uniform coating process may be not performed, so that color deflections may occur.

### SUMMARY OF THE INVENTION

Accordingly, it is an object of the present invention to provide a method for manufacturing a white LED in which a heat-induced degradation and a luminance down phenomenon occurring when a blue chip and a phosphorous material contact with each other may be prevented by forming lamps through two lamp molding steps.

It is another object of the present invention to provide a method for manufacturing a white LED in which it is possible to obtain a long time storage effect from a first lamp molding step to a second lamp molding step.

It is further another object of the present invention to provide a method for manufacturing a white LED in which it is possible to emit a perfect white light with less color deflection based on a uniform coating of a phosphorous material.

To achieve the above objects, in a method for manufacturing a white LED which emits a white light by changing a wavelength of a blue light as a phosphorous material is excited by a blue light from a blue chip, there is provided a method for manufacturing a white LED which comprises a die bonding step in which a blue chip is mounted on a lead frame; a wire bonding step in which the blue chip and lead frame both mounted on the lead frame in the die bonding step are electrically connected by a wire; a first lamp molding step in which a first lamp is formed on the blue chip which is electrically connected with the lead frame in the wire bonding step; a phosphorous material coating step in which a phosphorous material is coated on the first lamp formed in the first lamp molding step; and a second lamp molding step in which a second lamp is formed on the first lamp which is previously coated with the phosphorous material in the phosphorous material coating step.

To achieve the above objects, in a method for manufacturing a white LED which emits a white light by changing a wavelength of a blue light as a phosphorous material is excited by a blue light from a blue chip, there is provided a method for manufacturing a white LED which comprises a die bonding step in which a blue chip is mounted on a lead frame; a wire bonding step in which the blue chip and lead frame both mounted on the lead frame in the die bonding step are electrically connected by a wire; a coating layer forming step in which a coating layer is formed on the blue chip which is electrically connected with the lead frame in the wire bonding step; a first lamp molding step in which a first lamp is formed on the coating layer formed in the coating layer forming step; and a second lamp molding step in which a second lamp is formed on the first lamp formed in the first lamp molding step.

The first lamp is made by mixing a phosphorous material and an epoxy resin.

### BRIEF DESCRIPTION OF THE DRAWINGS

The present invention will become better understood with reference to the accompanying drawings which are given only by way of illustration and thus are not limitative of the present invention, wherein;

FIG. 1 is a cross sectional view illustrating a white LED according to an embodiment of the present invention;

FIG. 2 is a flow chart of a method for manufacturing a white LED according to an embodiment of the present invention;

FIG. 3 is a cross sectional view illustrating a white LED according to another embodiment of the present invention; and

FIG. 4 is a flow chart of a method for manufacturing a white LED according to another embodiment of the present invention.

### DETAILED DESCRIPTION OF THE PREFERRED EMBODIMENTS

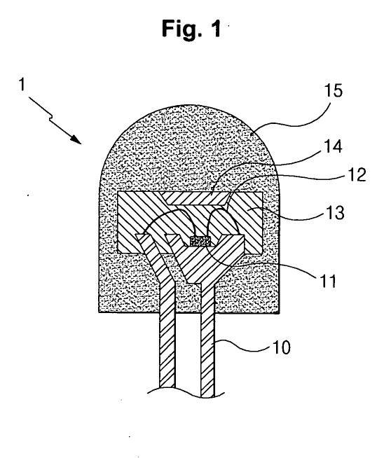

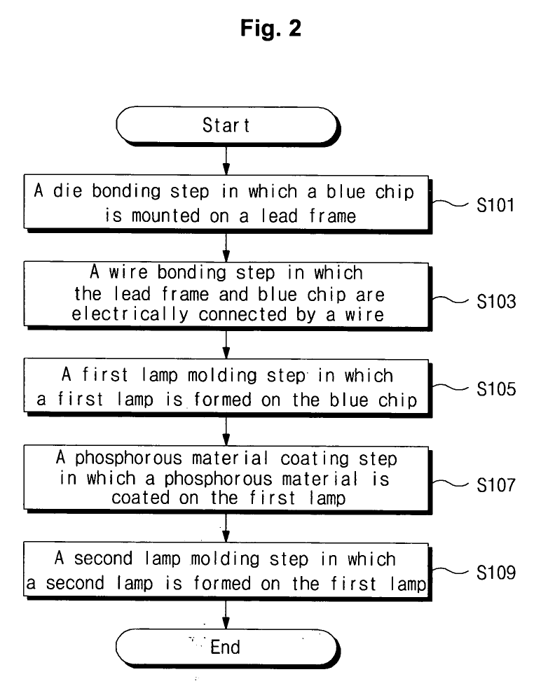

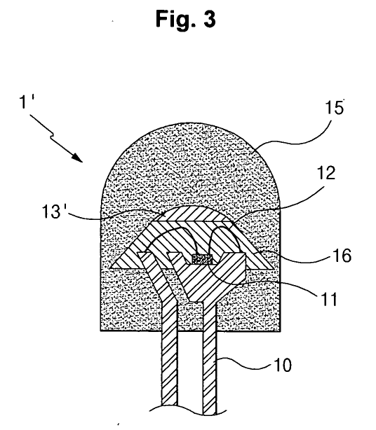

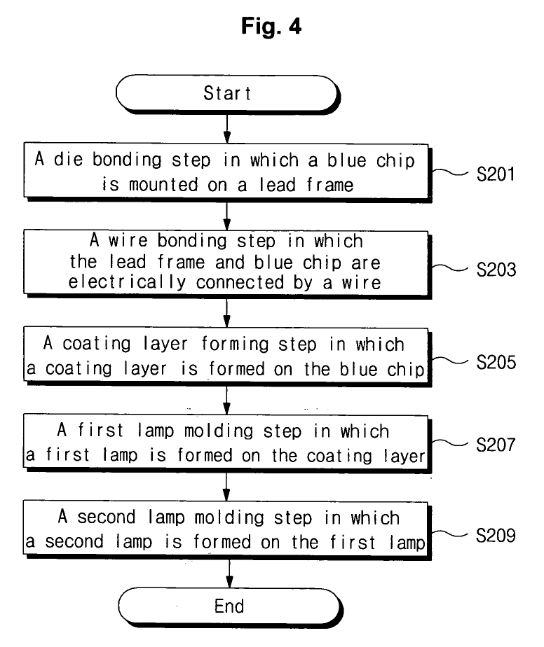

FIG. 1 is a cross sectional view illustrating a white LED according to an embodiment of the present invention, FIG. 2 is a flow chart of a method for manufacturing a white LED according to an embodiment of the present invention, FIG. 3 is a cross sectional view illustrating a white LED according to another embodiment of the present invention, and FIG. 4 is a flow chart of a method for manufacturing a white LED according to another embodiment of the present invention.

According to an embodiment of the present invention in a method for manufacturing a white LED which emits a white light by changing a wavelength of a blue light as a phosphorous material is excited by a blue light from a blue chip 11, there is provided a method for manufacturing a white LED which comprises a die bonding step S101 in which a blue chip 11 is mounted on a lead frame 10; a wire bonding step S103 in which the blue chip 11 and lead frame 10 both mounted on the lead frame 10 in the die bonding step S101 are electrically connected by a wire 12; a first lamp molding step S105 in which a first lamp 13 is formed on the blue chip 11 which is electrically connected with the lead frame 10 in the wire bonding step S103; a phosphorous material coating step S107 in which a phosphorous material 14 is coated on the first lamp 13 formed in the first lamp molding step S105; and a second lamp molding step S109 in which a second lamp 15 is formed on the first lamp 13 which is previously coated with the phosphorous material 14 in the phosphorous material coating step S107.

In the above die bonding step S101, a blue chip 11 is mounted on the lead frame 10. It is preferred to bond a blue chip 11 on the lead frame, the blue chip being made of an insulation epoxy or a conductive epoxy.

The blue chip 11 mounted on the lead frame 10 is electrically connected by a wire 12 in the wire bonding step S103. An electric power is supplied through the wire 12, so that the blue chip 11 emits light.

The wire 12 may be made of an aluminum wire, but may be preferably made of a gold wire. The gold wire has a thickness of 1 mil(about 25 um and is made of a six-nine gold(99.999%) of a very high purity.

A first lamp 13 is formed on the blue chip 11 in a first lamp molding step S105, the blue chip 11 being connected with the lead frame 10 in the wire bonding step S103. A phosphorous material 13, which will be described later, is coated on the first lamp 13. Here, the first lamp 13 is preferably made of an epoxy resin.

A phosphorous material 14 is coated on the first lamp 13, which is made of an epoxy resin, in a phosphorous material coating step S107. Here, the phosphorous material 14 changes the wavelength of a blue light emitted from the blue chip 11 for thereby emitting a white light.

A second lamp 15 is formed on the first lamp 13 in a second lamp molding step S109, the first lamp 13 being coated with the phosphorous material 14 in the phosphorous material coating step S107. The second lamp 15 forms a whole outer construction of the white LED 1 and is preferably made of an epoxy resin like the first lamp 13.

The present invention will be described in more detail with reference to FIGS. 1 and 2.

First, the blue chip 11 is bonded on the lead frame 10 by using an insulation epoxy in the die bonding step S101.

In the wire bonding step S103, the blue chip 11 and the lead frame 10 are electrically connected by the wire 12. Here, the wire 12 is made of a gold wire.

In the first lamp molding step S105, the first lamp 13 is formed on the blue chip 11. Here, the first lamp 13 is made of an epoxy resin.

In the phosphorous material coating step S107, the phosphorous material 14 is uniformly coated on an upper surface and a side surface of the first lamp 13, respectively.

In the second lamp molding step S109, the second lamp 15 is formed on the first lamp 13 on which the phosphorous material 14 is coated. Here, the second lamp 15 is made of an epoxy resin like the first lamp 13.

FIGS. 3 and 4 are a cross sectional view of the white LED 1′ and a flow chart of the method for manufacturing the same according to another embodiment of the present invention.

According to another embodiment of the present invention in a method for manufacturing a white LED which emits a white light by changing a wavelength of a blue light as a phosphorous material is excited by a blue light from a blue chip 11, there is provided a method for manufacturing a white LED which comprises a die bonding step S201 in which a blue chip 11 is mounted on a lead frame 10; a wire bonding step S203 in which the blue chip 11 and lead frame 10 both mounted on the lead frame 10 in the die bonding step S201 are electrically connected by a wire; a coating layer forming step S205 in which a coating layer 16 is formed on the blue chip 11 which is electrically connected with the lead frame 10 in the wire bonding step S203; a first lamp molding step S207 in which a first lamp 13′ is formed on the coating layer 16 formed in the coating layer forming step S205; and a second lamp molding step S209 in which a second lamp 15 is formed on the first lamp 13′ formed in the first lamp molding step S207.

According to the method for manufacturing a white LED according to another embodiment of the present invention, a coating layer 16 is formed on the blue chip 11 using an epoxy resin, the blue chip 11 being mounted on the lead frame 10 and being electrically connected by a wire 12. A first lamp 13′ is formed on the coating layer 16 by mixing a phosphorous material and an epoxy resin, and then a second lamp 15 is formed on the first lamp 13′ using an epoxy resin. The descriptions of each step and operation are same as the method for manufacturing a white LED according to a first embodiment of the present invention, so that the detailed descriptions of the same will be omitted.

As described above, as compared to the conventional art in which a phosphorous material is directly coated on the chip for thereby disadvantageously generating a heat-induced degradation problem, the method for manufacturing a white LED according to the present invention can prevent heat-induced degradation problems through two lamp molding steps, which degradation problems occur due to heating since a blue chip and a phosphorous material directly contact with each other, so that a reliable product can be manufactured.

In addition, a long time storage from a first lamp molding step to a second lamp molding step can be obtained.

In the present invention, a perfect white light with less color deflection can be obtained since a phosphorous material is uniformly coated.

As the present invention may be embodied in several forms without departing from the spirit or essential characteristics thereof, it should also be understood that the above-described examples are not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

What is claimed is:

1. In a method for manufacturing a white LED which emits a white light by changing a wavelength of a blue light as a phosphorous material is excited by a blue light from a blue chip, a method for manufacturing a white LED, comprising:
a die bonding step in which a blue chip is mounted on a lead frame;
a wire bonding step in which the blue chip and lead frame both mounted on the lead frame in the die bonding step are electrically connected by a wire;
a first lamp molding step in which a first lamp is formed on the blue chip which is electrically connected with the lead frame in the wire bonding step;
a phosphorous material coating step in which a phosphorous material is coated on the first lamp formed in the first lamp molding step; and
a second lamp molding step in which a second lamp is formed on the first lamp which is previously coated with the phosphorous material in the phosphorous material coating step.

2. In a method for manufacturing a white LED which emits a white light by changing a wavelength of a blue light as a phosphorous material is excited by a blue light from a blue chip, a method for manufacturing a white LED, comprising:
a die bonding step in which a blue chip is mounted on a lead frame;
a wire bonding step in which the blue chip and lead frame both mounted on the lead frame in the die bonding step are electrically connected by a wire;
a coating layer forming step in which a coating layer is formed on the blue chip which is electrically connected with the lead frame in the wire bonding step;
a first lamp molding step in which a first lamp is formed on the coating layer formed in the coating layer forming step; and
a second lamp molding step in which a second lamp is formed on the first lamp formed in the first lamp molding step.

3. The method of claim 2, wherein said first lamp is made by mixing a phosphorous material and an epoxy resin.
